(19) United States
(12) Patent Application Publication
(10) Pub. No.: US 2025/0294768 A1
(43) Pub. Date: Sep. 18, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Jee Hyun KIM, Gyeonggi-do (KR); Byung Soo PARK, Gyeonggi-do (KR); Yu Jin KWON, Gyeonggi-do (KR); Jeong Seob OH, Gyeonggi-do (KR); Jin Won LEE, Gyeonggi-do (KR)

(21) Appl. No.: 18/738,072

(22) Filed: Jun. 10, 2024

(30) Foreign Application Priority Data
Mar. 18, 2024 (KR) 10-2024-0036920

(51) Int. Cl. H10B 43/40; H10B 41/10; H10B 41/27; H10B 41/40; H10B 43/10; H10B 43/27

(52) U.S. Cl. CPC H10B 43/40; H10B 41/10; H10B 41/27; H10B 41/40; H10B 43/10; H10B 43/27

(57) ABSTRACT

A semiconductor device may include a gate structure including conductive layers and insulating layers that are alternately stacked; support structures respectively located at vertices of a polygon defined on an upper surface of the gate structure and each support structure including a pillar extending through the gate structure and protrusion portions protruding from the pillar toward the conductive layers; and a contact structure extending through the gate structure inside the polygon and electrically connected to a first conductive layer of the conductive layers, wherein the protrusion portions may include first protrusion portions in contact with the contact structure and second protrusion portions located below the contact structure.

### CROSS-REFERENCE TO RELATED APPLICATION

This patent application claims priority under 35 U.S.C. § 119 to Korean Patent Application No. 10-2024-0036920 filed on Mar. 18, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment of the present disclosure, a semiconductor device may include a gate structure including conductive layers and insulating layers that are alternately stacked; support structures (also referred to simply as supports) respectively located at vertices of a polygon defined on an upper surface of the gate structure and each support structure including a pillar extending through the gate structure and protrusion portions protruding from the pillar toward the conductive layers; and a contact structure extending through the gate structure inside the polygon and electrically connected to a first conductive layer of the conductive layers, wherein the protrusion portions may include first protrusion portions in contact with the contact structure and second protrusion portions located below the contact structure.

In an embodiment of the present disclosure, a semiconductor device may include a gate structure including conductive layers and insulating layers that are alternately stacked; support structures respectively located at vertices of a polygon defined on an upper surface of the gate structure and each including a pillar extending through the gate structure and protrusion portions protruding from the pillar toward the conductive layers; and a contact structure extending through the gate structure inside the polygon and electrically connected to a first conductive layer of the conductive layers, wherein the support structures arranged along a perimeter of the polygon may be spaced apart from each other, and the contact structure may be in contact with the protrusion portions of the support structures.

In an embodiment, a manufacturing method of a semiconductor device may include forming a stack including first material layers and second material layers that are alternately stacked; forming sacrificial support structures extending through the stack and respectively located at vertices of a polygon defined on an upper surface of the stack; forming a sacrificial contact structure extending through the stack inside the polygon and including a lower region, an upper region and a bowing region located between the lower region and the upper region, the bowing region having a greater width than the lower region and the upper region; forming first openings by removing the sacrificial support structures; forming second openings by selectively etching the first material layers through the first openings so that the lower region of the sacrificial contact structure is exposed; forming support structures in the first openings and the second openings; replacing the first material layers with conductive layers; and replacing the sacrificial contact structure with a contact structure. These and other features and advantages of the embodiments of the present disclosure will become better understood by the skilled person after having read the detailed description of various embodiments illustrated in the following drawings.

### BRIEF DESCRIPTION OF THE DRAWINGS

FIGS. 1A to 1D are simplified schematic diagrams illustrating the structure of a semiconductor device in accordance with an embodiment of the present disclosure.

FIGS. 2A to 2D are simplified schematic diagrams illustrating the structure of a semiconductor device in accordance with an embodiment of the present disclosure.

FIGS. 3A and 3B are simplified schematic diagrams illustrating the structure of a semiconductor device in accordance with an embodiment of the present disclosure.

FIG. 4 is a diagram illustrating the structure of a semiconductor device in accordance with an embodiment of the present disclosure.

FIGS. 5A, 5B, 6A, 6B, 7A to 7D, 8A, and 8B are simplified schematic diagrams for describing a manufacturing method of a semiconductor device in accordance with an embodiment of the present disclosure.

FIG. 9 is a diagram for describing a modified example of a manufacturing method of a semiconductor device in accordance with an embodiment of the present disclosure.

FIGS. 10A and 10B are simplified schematic diagrams for describing a modified example of a manufacturing method of a semiconductor device in accordance with an embodiment of the present disclosure.

FIG. 11 is a configuration diagram of a semiconductor device in accordance with an embodiment of the present disclosure.

FIG. 12 is a configuration diagram of a semiconductor device in accordance with an embodiment of the present disclosure.

### DETAILED DESCRIPTION

Various embodiments of the present disclosure are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

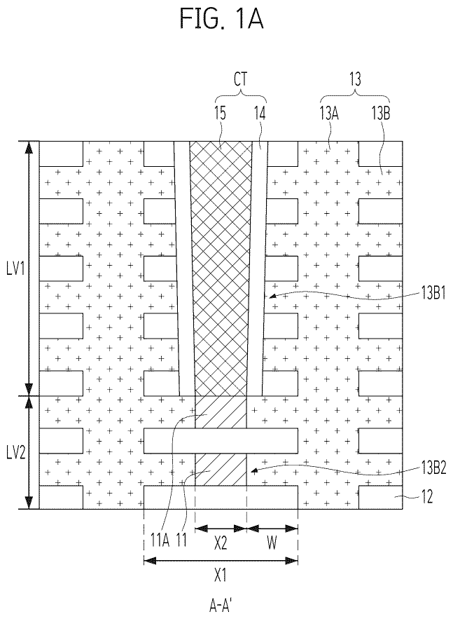

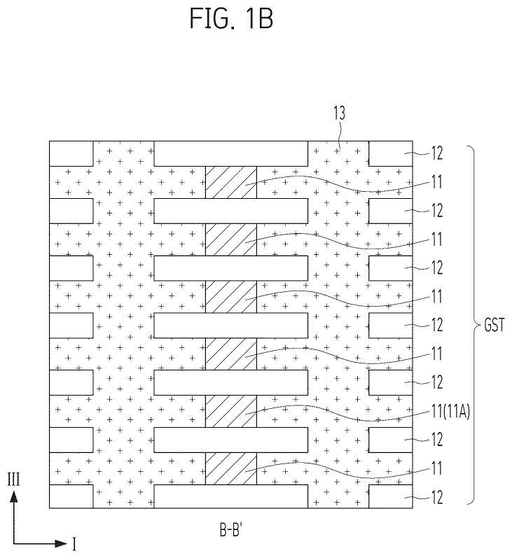

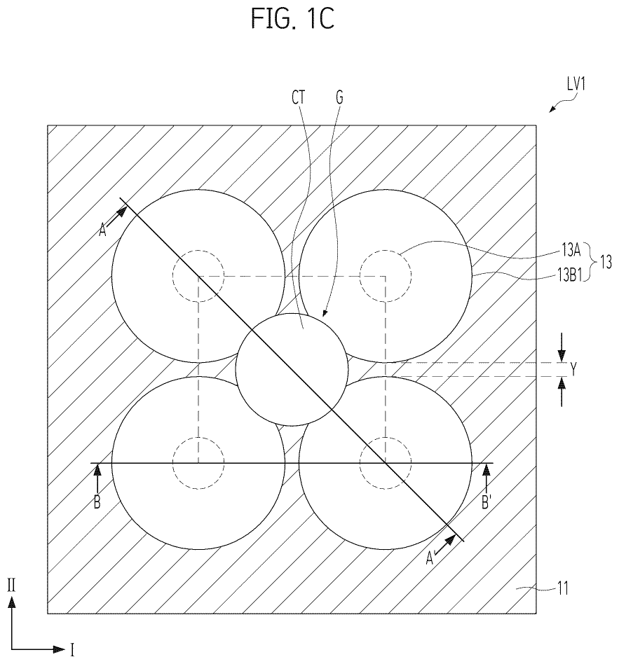

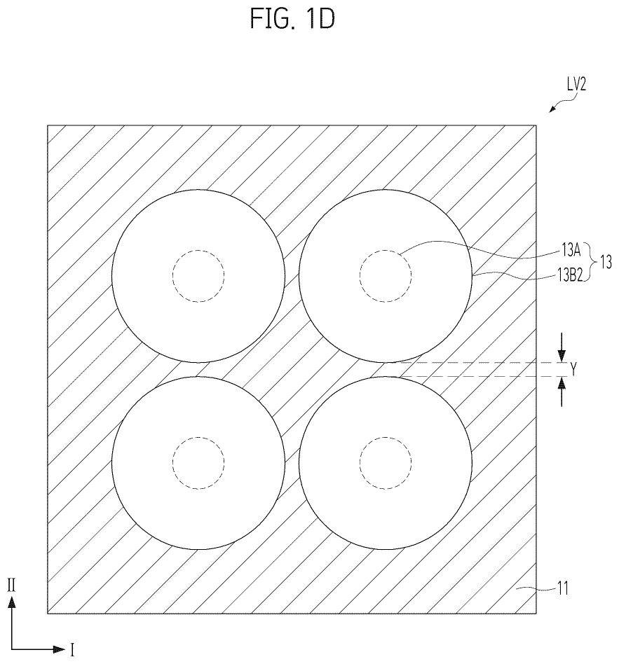

FIGS. 1A to 1D are simplified schematic diagrams illustrating the structure of a semiconductor device in accordance with an embodiment of the present disclosure.

Referring to FIGS. 1A to 1D, the semiconductor device may include a gate structure GST, support structures 13, and a contact structure CT. The gate structure GST may include conductive layers 11 and insulating layers 12 that are alternately stacked. In an embodiment, the conductive layers 11 may be gate lines such as word lines, source select lines, or drain select lines. The conductive layers 11 may each include a conductive material such as, for example, polysilicon, tungsten, or molybdenum. The insulating layers 12 are used to insulate the stacked conductive lines 11 from each other. Each conductive layer 11 may include an insulating material such as, for example, oxide, nitride, or air gap.

The support structures 13 may extend vertically in a third direction III through the gate structure GST. The third direction III refers to the stacking direction of the conductive layers 11 and the insulating layers 12. In a plan view, the support structures 13 may be arranged in a first direction I and a second direction II intersecting the first direction I. As an example, a polygon may be defined on an upper surface of the gate structure GST, and the support structures 13 may be located at vertices of the polygon, respectively. The support structures 13 arranged along the perimeter of the polygon may be spaced apart from each other. Here, the polygon may be a square.

Referring to FIGS. 1C and 1D, four support structures 13 may be located at the four vertices of a square, respectively. The four support structures 13 arranged along the perimeter of the square may be spaced apart from each other. The four support structures 13 may be arranged at the four vertices of the a square and may be sized so that they may not come into contact with each other.

Each of the support structures 13 may include a pillar 13A and protrusion portions 13B. The pillar 13A refers to an elongated column extending along the third direction III. The protrusion portions 13B may protrude laterally (e.g., horizontally) from sidewalls of the pillar 13A. The cross-section of the pillar 13A may have a circle shape. However, the embodiment is not limited thereto, and in variations of the described embodiment the cross-section may be rectangular, or oval. A plurality of protrusion portions 13B may be connected to one pillar 13A, and the protrusion portions 13B may be located to correspond to the conductive layers 11. The protrusion portions 13B may protrude toward their corresponding conductive layers 11. The protrusion portions 13B may be spaced apart from each other at a regular interval along the third direction III.

The contact structure CT may be located between the support structures 13 as shown in the embodiment of FIG. 1A. As an example, the contact structure CT may be located inside the polygon defined by the support structures 13, and may be located to correspond to the center of the polygon (See FIG. 1C). The center of the contact structure CT may coincide with the center of the polygon or the center of the polygon may be located in a region covered by the contact structure CT in a plan view. The contact structure CT may extend vertically in the third direction III through the gate structure GST, and may be electrically connected to a first conductive layer 11A of the conductive layers 11. As an example, a plurality of contact structures CT having different depths may be connected to the conductive layers 11, respectively. In a cross section, the contact structure CT may have a tapered shape or a bowing shape. For example, as shown in FIG. 1A the cross-section of the contact structure CT may be decreasing in a direction opposite to the stacking direction of the gate structure GST.

The contact structure CT may include a contact plug 15 and an insulating spacer 14 surrounding sidewalls of the contact plug 15. The contact plug 15 may be electrically connected to the first conductive layer 11A. The insulating spacer 14 may insulate the conductive layers located above the first conductive layer 11A and the contact plug 15, from each other.

The contact structure CT may be in contact with the surrounding support structures 13. For example, as best illustrated in FIG. 1C, the contact structure CT located at the center of the polygon may be in contact with the support structures 13 located at the vertices of the polygon. Depending on whether or not the protrusion portions 3B are in contact with the contact structure CT, the protrusion portions 13B may be divided into first protrusion portions 13B1 or second protrusion portions 13B2. The first protrusion portions 13B1 and the second protrusion portions 13B2 may have different shapes. For example, the second protrusion portions 13B2 may have a normal shape for example, a symmetrical shape such as a circular shape or an elliptical shape, that does not include a groove G, and the first protrusion portions 13B1 may have an abnormal shape that includes the groove G.

The first protrusion portions 13B1 may be located at a first level range LV1 corresponding to the contact structure CT. The contact structure CT may be located between the first protrusion portions 13B1, and the first protrusion portions 13B1 and the contact structure CT may be in contact with each other. The first protrusion portions 13B1 may each include the groove G surrounding a sidewall of the contact structure CT, and may have an asymmetric shape in which a portion thereof is depressed due to the groove G. The contact structure CT may fill the groove G.

The second protrusion portions 13B2 may be located at a second level range LV2 that does not correspond to the contact structure CT, and may be located below the contact structure CT. Because the contact structure CT does not exist between the second protrusion portions 13B2 at the second level range LV2, the second protrusion portions 13B2 do not include the groove. Accordingly, the second protrusion portions 13B2 may have a normal shape, and may have a symmetrical shape such as a circular shape or an elliptical shape.

According to the structure described above, a distance between the support structures 13 may be adjusted by the protrusion portions 13B. Even though the pillars 13A are spaced apart from each other by a first distance X1, the distance between the support structures 13 may be narrowed to a second distance X2 by the protrusion portions 13B. Accordingly, it is possible to increase supporting force for a stack in a manufacturing process, and it is possible to reduce tilt or collapse of the stack.

In addition, by increasing a width W of the first protrusion portions 13B1 and the second protrusion portions 13B2, the second distance X2 may be narrowed and the support force may be further increased. However, a value of the width W should be determined in consideration of a distance Y between adjacent support structures 13. When the width W is increased so that the adjacent support structures 13 are in contact with each other along the perimeter of the polygon, the first conductive layer 11A outside the polygon and the first conductive layer 11A inside the polygon may be electrically disconnected to each other. Accordingly, the protrusion portions 13B should be spaced apart from each other so that the first conductive layers 11A are continuously connected to each other outside and inside the polygon, and the width W should be increased in a range in which the distance Y is secured.

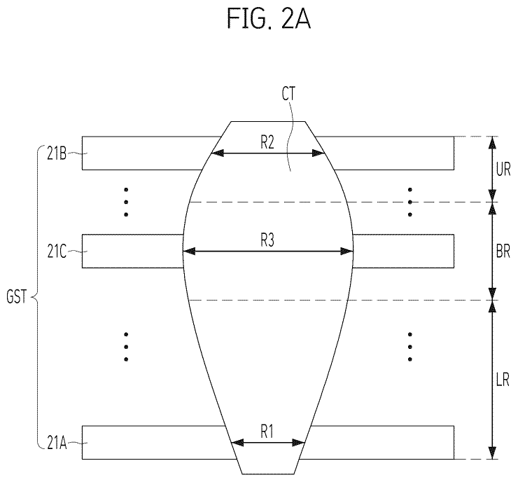

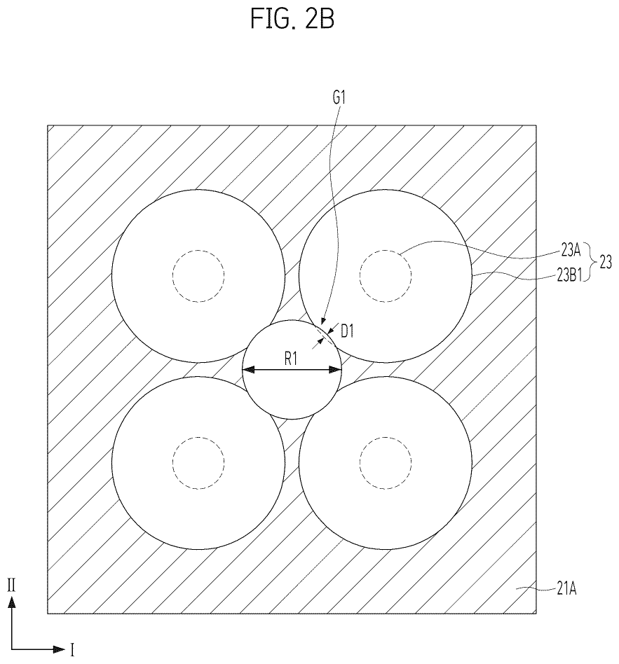

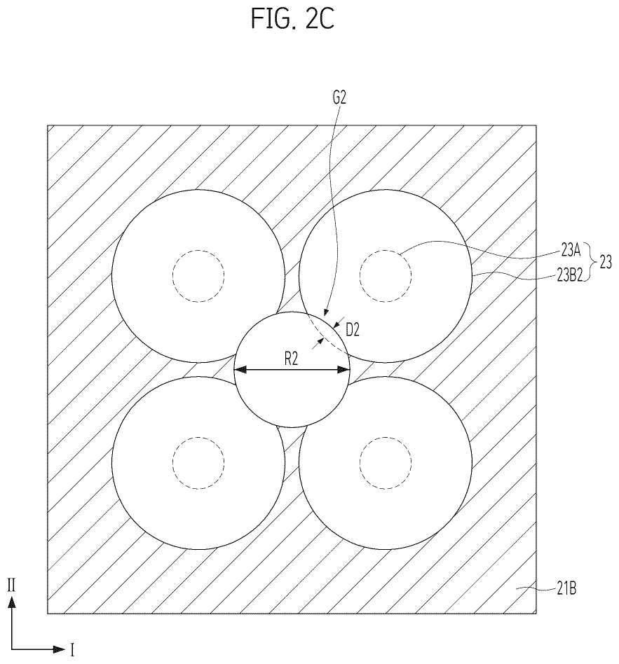

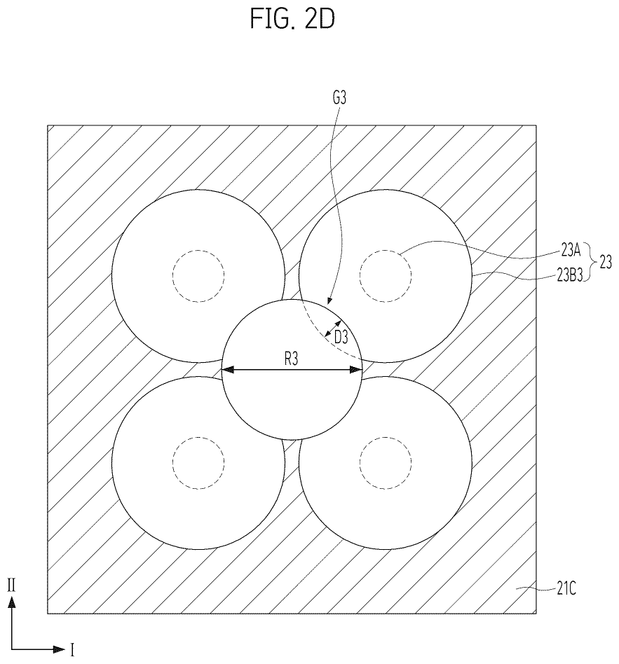

FIGS. 2A to 2D are simplified schematic diagrams illustrating the structure of a semiconductor device in accordance with an embodiment of the present disclosure. Hereinafter, the content overlapping with the previously described content may be omitted.

Referring to FIGS. 2A to 2D, the semiconductor device may include a gate structure GST, a contact structure CT, and support structures 23. The gate structure GST may include conductive layers 21A to 21C that are stacked, and the contact structure CT may extend in the third direction III (i.e., a vertical direction) through the gate structure GST. The support structure 23 may include a pillar 23A and protrusion portions 23B1, 23B2, and 23B3. The cross-section of the pillar 23A may have a circle shape. However, the embodiment is not limited thereto, and in variations of the described embodiment the cross-section may be rectangular, or oval.

As an example, the contact structure CT may have a cross section with a bowing shape. More specifically, as illustrated in FIG. 2A, the contact structure CT may include a lower region LR, a bowing region BR, and an upper region UR. The lower region LR may include a lower surface of the contact structure CT, the upper region UR may include an upper surface of the contact structure CT, and the bowing region BR may be located between the upper region UR and the lower region LR. The lower region LR may have a first width R1, the upper region UR may have a second width R2, and the bowing region BR may have a third width R3. Here, the third width R3 may be greater than the first width R1 and the second width R2.

Depending on the regions, the protrusion portions 23B1, 23B2, and 23B3 may include grooves G1, G2, and G3 having different depths. Referring to FIG. 2B, in the lower region LR, the contact structure CT may have the first width R1, and a first protrusion portion 23B1 may include a first groove G1 having a first depth D1. Referring to FIG. 2C, in the upper region UR, the contact structure CT may have the second width R2, and a second protrusion portion 23B2 may include a second groove G2 having a second depth D2. Referring to FIG. 2D, in the bowing region BR, the contact structure CT may have the third width R3, and a third protrusion portion 23B3 may include a third groove G3 having a third depth D3.

Here, the second width R2 may be greater than the first width R1, and the second depth D2 may be greater than the first depth D1. The third width R3 may be greater than the first width R1 and the second width R2, and the third depth D3 may be greater than the first depth D1 and the second depth D2.

According to the structure described above, the contact structure CT may have the cross section with the bowing shape, and may be in contact with the surrounding support structures 23 regardless of the width of the various regions of the contact structure CT. The first to third protrusion portions 23B1, 23B2, and 23B3 may include the first to third grooves G1, G2, and G3, respectively, and depths of the grooves may be different from each other depending on the widths of the contact structure CT. The overall sidewall of the contact structure CT may have a continuous curve profile bulging in the bowing region BR located between a lower region LR and an upper region UR.

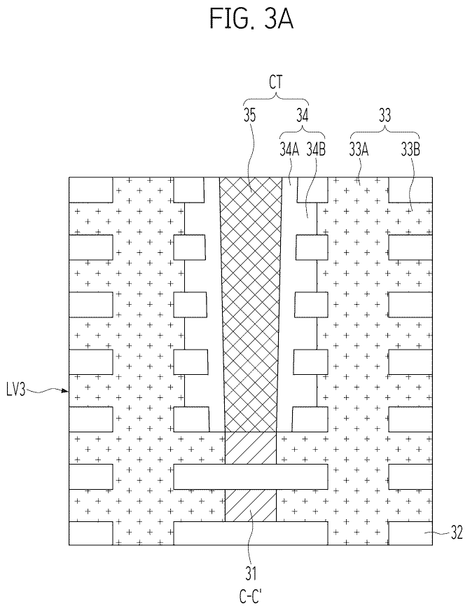

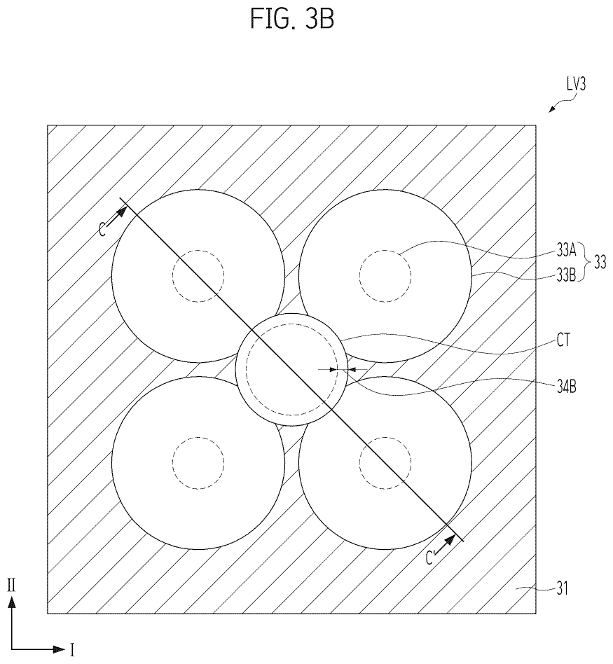

FIGS. 3A and 3B are simplified schematic diagrams illustrating the structure of a semiconductor device in accordance with an embodiment of the present disclosure. FIG. 3A is a cross-sectional view taken along line C-C′ of FIG. 3B. Hereinafter, any content overlapping with the previously described content may be omitted.

Referring to FIGS. 3A and 3B, the semiconductor device may include conductive layers 31, insulating layers 32, a contact structure CT, and support structures 33. The support structures 33 may each include a pillar 33A and protrusion portions 33B. The contact structure CT may include a contact plug 35 and an insulating spacer 34 surrounding the contact plug 35. The insulating spacer 34 may include a sidewall pattern 34A and protrusion patterns 34B. The protrusion patterns 34B may protrude from the sidewall pattern 34A toward the conductive layers 31. The protrusion portion patterns 34B may be located to correspond to the protrusion portions 33B, and may be in contact with the protrusion portions 33B.

The support structures 33 may be arranged at vertices of a polygon, and the contact structure CT may be located at the center of the polygon. The contact structure CT may be in contact with the surrounding support structures 33. The contact structure CT may have a shape whose width is increased by the protrusion pattern 34B. A distance between the contact plug 35 and the conductive layer 31 may be increased by the protrusion pattern 34B, and a breakdown voltage may be secured.

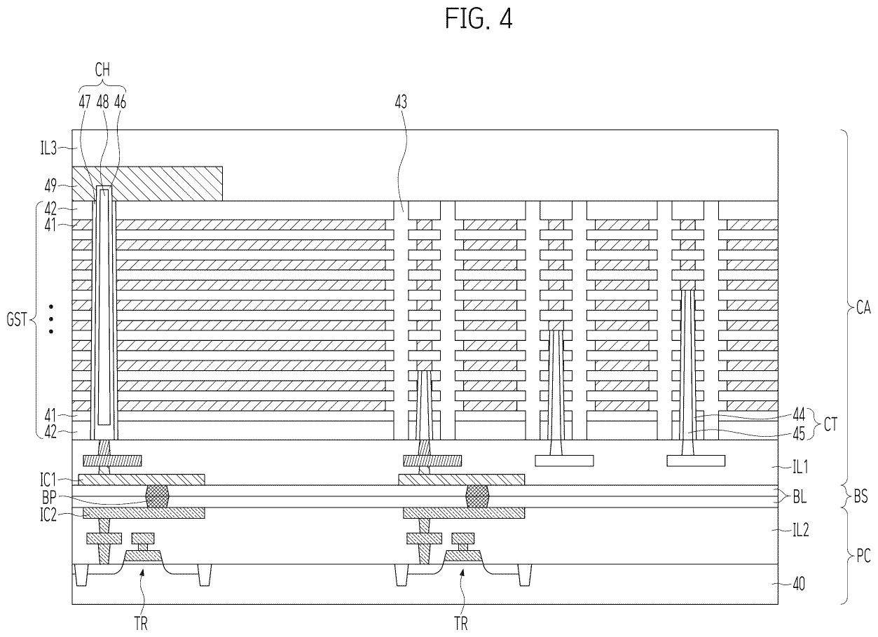

FIG. 4 is a diagram illustrating the structure of a semiconductor device in accordance with an embodiment of the present disclosure.

Referring to FIG. 4, the semiconductor device may include a peripheral circuit PC, a bonding structure BS, and a memory cell array CA. The bonding structure BS may be located between the peripheral circuit PC and the memory cell array CA, and may include a bonding layer BL and a bonding pad BP electrically connecting the peripheral circuit PC and the memory cell array CA to each other.

The memory cell array CA may include a gate structure GST, contact structures CT, and support structures 43. The memory cell array CA may further include at least one of a channel structure CH, a source structure 49, a first interconnection structure IC1, a first interlayer insulating layer IL1, and a third interlayer insulating layer IL3.

The gate structure GST may include conductive layers 41 and insulating layers 42 that are alternately stacked. The source structure 49 may be located on the gate structure GST. The third interlayer insulating layer IL3 may be located on the source structure 49. The third interlayer insulating layer IL3 may be located on any remaining section of the gate structure GST that is not covered by the source structure 49. The channel structure CH may extend vertically through the gate structure GST and slightly into the source structure 49. The channel structure CH may include a channel layer 46, a memory layer 47 surrounding the channel layer 46, and an insulating core 48 located in the channel layer 46. The first interconnection structure IC1 may be connected to the channel structure CH and/or the contact structure CT. The first interconnection structure IC1 may be located in the first interlayer insulating layer IL1 and may include at least one via extending vertically and at least one line extending parallel to the gate structure GST.

The support structures 43 may extend vertically through the gate structure GST. The support structures 43 may include protrusion portions protruding toward the conductive layers 41. The contact structure CT may be located between the support structures 43. The contact structure CT may include an insulating spacer 44 and a contact plug 45. The contact structure CT may be in contact with the surrounding support structures 43. As described above with reference to FIGS. 3A and 3B, it is also possible for the insulating spacer 44 to include protrusion patterns.

The peripheral circuit PC may include a transistor TR located on a substrate 40. As an example, the peripheral circuit PC may be a page buffer, a row decoder, a logic circuit, or the like. A second interconnection structure IC2 may be connected to the peripheral circuit PC, and may be located in a second interlayer insulating layer IL2.

According to the structure described above, the memory cell array CA and the peripheral circuit PC may be electrically connected to each other through the bonding structure BS. The support structures 43 include the protrusion portions, and accordingly, structural stability may be ensured in a manufacturing process.

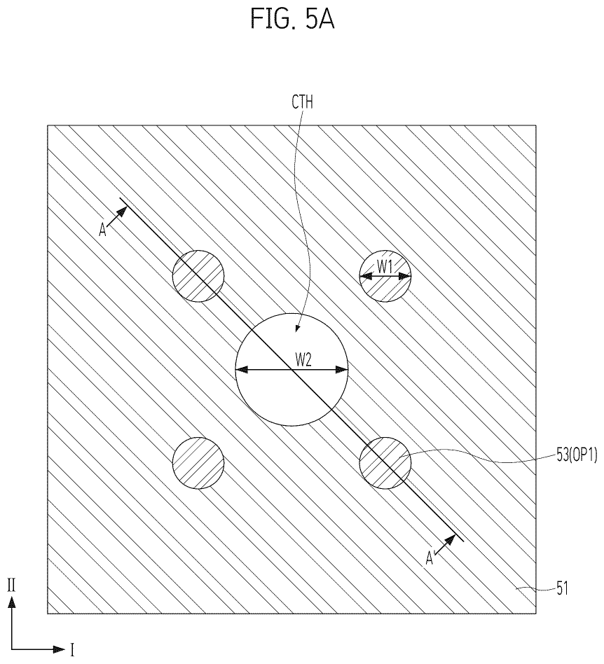

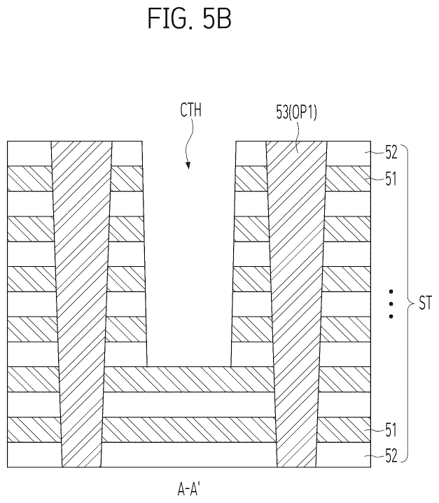

FIGS. 5A, 5B, 6A, 6B, 7A to 7D, 8A, and 8B are simplified schematic diagrams for describing a manufacturing method of a semiconductor device in accordance with an embodiment of the present disclosure. FIGS. 5A, 6A, 7A, and 8A are plan views, and FIGS. 5B, 6B, 7B, and 8B are cross-sectional views taken along lines A-A′ of FIGS. 5A, 6A, 7A, and 8A, respectively.

Referring to FIGS. 5A and 5B, a stack ST may be formed including first and second material layers 51 and 52 that are alternately stacked. The first material layers 51 may each include a material having a high etching selectivity with respect to the second material layers 52. The first material layers 51 may be used to form gate lines. As an example, the first material layers 51 may each include a sacrificial material such as nitride or a conductive material such as polysilicon or metal. The second material layers 52 are used to insulate the stacked gate lines from each other, and may each include an insulating material such as, for example, oxide, nitride, or air gap.

Subsequently, first openings OP1 may be formed passing through the stack ST. The first openings OP1 may be arranged in the first and second directions I and II. In a plane defined by the first direction I and the second direction II, the first openings OP1 may be located at the vertices of a polygon, respectively. In a plan view, the first openings OP1 may each have a shape such as a circular shape or an elliptical shape. The first opening OP1 may have a first width W1. The first openings OP1 may be arranged along the perimeter of the polygon and may be spaced apart from each other.

Subsequently, sacrificial support structures 53 may be formed in the first openings OP1, respectively. The sacrificial support structures 53 may extend through the stack ST. The sacrificial support structures 53 may each have a cross section with a tapered shape or a bowing shape. The sacrificial support structures 53 may each include a material having an etching selectivity with respect to the first material layers 51 and the second material layers 52. As an example, the sacrificial support structures 53 may each include a carbon layer.

For example, when the first openings OP1 are formed, a channel hole, a slit, and the like, may be formed together. In such a case, when the sacrificial support structures 53 are formed, a sacrificial channel layer may be formed in the channel hole and a sacrificial slit layer may be formed in the slit. In addition, after the sacrificial channel layer is selectively removed, a channel structure may be formed.

Subsequently, a contact hole CTH may be formed in the stack ST. As an example, a plurality of contact holes CTH having different depths may be formed to expose the first material layers 51. The contact hole CTH may be located between the first openings OP1. As an example, the contact hole CTH may be located at the center of the polygon, and may be spaced apart from the first openings OP1. The contact hole CTH may have a cross section with a tapered shape or a bowing shape. The contact hole CTH may have a second width W2 greater than the first width W1.

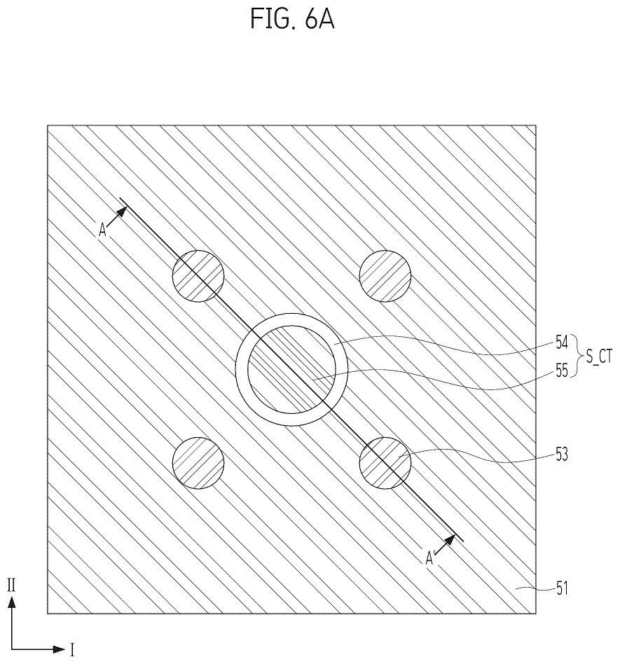

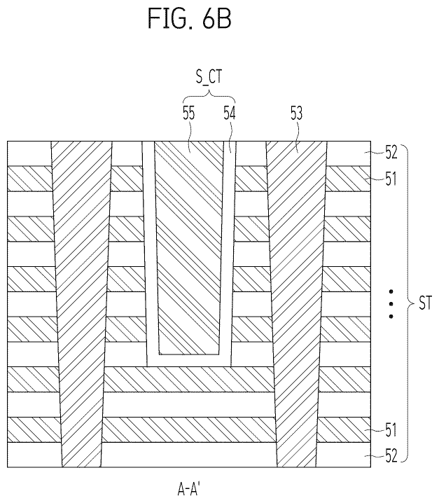

Referring to FIGS. 6A and 6B, a sacrificial contact structure S_CT may be formed in the contact hole CTH. After an insulating liner 54 is formed in the contact hole CTH, a sacrificial layer 55 may be formed in the insulating liner 54. The insulating liner 54 may include an insulating material such as, for example, oxide. The sacrificial layer 55 may include a material having a high etching selectivity with respect to the insulating liner 54, and may include tungsten.

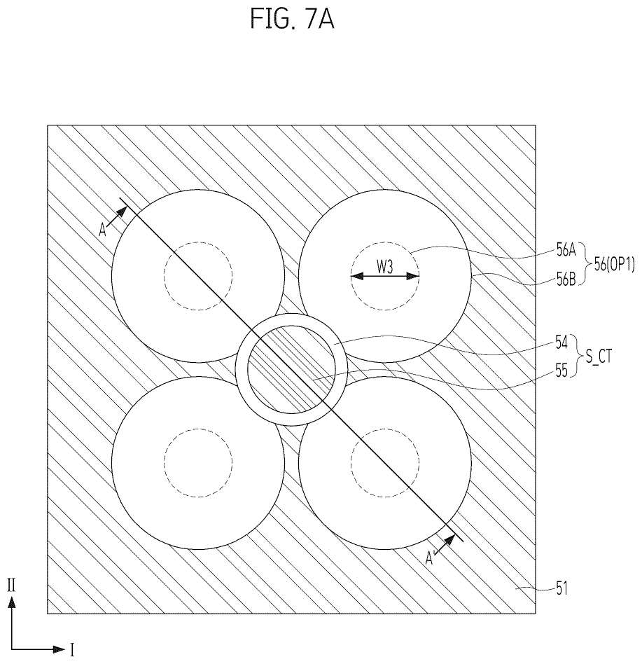

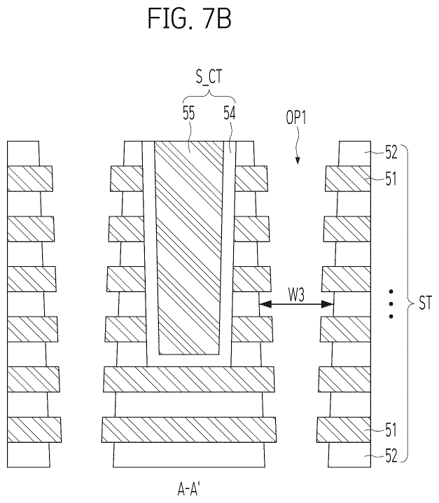

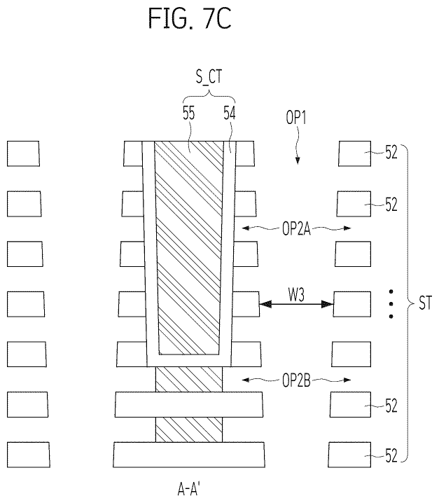

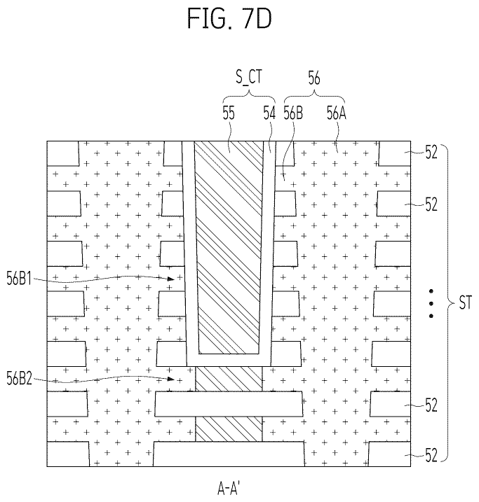

Referring to FIGS. 7A to 7D, the sacrificial support structures 53 may be replaced with support structures 56. The support structures 56 may have a different shape from the sacrificial support structures 53, and may include a plurality of protrusion portions 56B. Here, the protrusion portions 56B may be used to stably support the stack ST.

First, referring to FIGS. 7A and 7B, the first openings OP1 may be reopened by removing the sacrificial support structures 53. Subsequently, the second material layers 52 exposed through the first openings OP1 may be selectively etched. Through this, a width of the first openings OP1 may increase to a third width W3, and irregularities may be formed on inner walls of the first openings OP1. The first material layers 51 may protrude into the first openings OP1.

A depth at which the second material layer 52 is etched may be determined in consideration of a width of a pillar formed in a subsequent process. The width W3 of the first opening OP1 defined by etching the second material layer 52 may correspond to the width of the pillar. When the second material layer 52 is etched more, the width of the pillar increases, and when the second material layer 52 is etched less, the width of the pillar decreases. Accordingly, the depth at which the second material layer 52 is etched may be determined in consideration of a shape of a support formed in a subsequent process.

Subsequently, referring to FIGS. 7A and 7C, second openings OP2 may be formed by selectively etching the first material layers 51 exposed through the first openings OP1. The second openings OP2 may be used to define the regions where the protrusion portions of the support structures are formed in a subsequent process. Accordingly, a depth at which the first material layers 51 are etched may be determined in consideration of a width of the protrusion portions.

In order for the support structures to stably support the stack ST, the protrusion portions should have a sufficient width. However, adjacent support structures should be spaced apart from each other, and the protrusion portions should not be connected to each other. Accordingly, a width of the second openings OP2 should be adjusted so that the protrusion portions having an appropriate width may be formed.

To this end, the first material layers 51 may be etched at a depth at which the sacrificial contact structure S_CT is exposed. In such a case, the second openings OP2 may have a sufficient width. In addition, adjacent second openings OP2 might not be connected to each other, and the first material layer 51 may remain between the adjacent second openings OP2.

When the sacrificial contact structure S_CT has a variable width depending on levels, depths of the first material layers 51 that should be etched in order to expose the sacrificial contact structure S_CT may be different from each other depending on the levels. As an example, when the sacrificial contact structure S_CT has a tapered shape or a bowing shape, the sacrificial contact structure S_CT may have a smaller width in a lower region thereof than the remaining region thereof. The sacrificial contact structure S_CT may have a minimum width in a lower surface thereof, and may have a maximum width in a bowing region or an upper region thereof. At a level at which the sacrificial contact structure S_CT has the minimum width, a distance between the sacrificial contact structure S_CT and the first opening OP1 may be greatest, and an etching depth of the first material layer 51 required to expose the sacrificial contact structure S_CT may be relatively great. At a level at which the sacrificial contact structure S_CT has the maximum width, a distance between the sacrificial contact structure S_CT and the first opening OP1 may be smallest, and an etching depth of the first material layer 51 required to expose the sacrificial contact structure S_CT may be relatively small.

Accordingly, the first material layers 51 may be etched based on the etching depth of the first material layer 51 at the level at which the sacrificial contact structure S_CT has the minimum width. As an example, the first material layers 51 may be etched at a depth at which the lower region of the sacrificial contact structure S_CT is exposed. In such a case, the upper region and the bowing region of the sacrificial contact structure S_CT as well as the lower region of the sacrificial contact structure S_CT may be exposed.

As the first material layers 51 are etched, second openings OP2A may be formed at a level that corresponds to the sacrificial contact structure S_CT, and second openings OP2B may be formed at a level that does not correspond to the sacrificial contact structure S_CT.

The sacrificial contact structure S_CT may be exposed through the second openings OP2A, and areas of the sacrificial contact structure S_CT exposed in each of the lower region, the upper region, and the bowing region may be different from each other. The area of the sacrificial contact structure S_CT exposed in the lower region may be small, and the area of the sacrificial contact structure S_CT exposed in the bowing region may be great.

The second openings OP2B may be located below the sacrificial contact structure S_CT. Because the second openings OP2B do not expose the sacrificial contact structure S_CT, the second openings OP2B may each have a normal shape such as a circular shape or an elliptical shape. By increasing a depth of the second openings OP2B, a width of the protrusion portions formed in a subsequent process may be increased, and greater support force may be secured.

Subsequently, referring to FIGS. 7A and 7D, support structures 56 may be formed in the first openings OP1 and the second openings OP2. Each of the support structures 56 may include a pillar 56A located in the first opening OP1 and protrusion portions 56B located in the second openings OP2.

Protrusion portions 56B1 located at the level that corresponds to the sacrificial contact structure S_CT among the protrusion portions 56B may be in contact with the sacrificial contact structure S_CT, and may include grooves surrounding sidewalls of the sacrificial contact structure S_CT. Due to the groove, each of the protrusion portions 56B1 may have an asymmetric shape. In addition, sizes of the grooves in each of the lower region, the upper region, and the bowing region may be different from each other. The groove of the protrusion portion 56B1 corresponding to the lower region may be relatively small, and the groove of the protrusion portion 56B1 corresponding to the bowing region may be relatively great.

Protrusion portions 56B2 located at the level that does not correspond to the sacrificial contact structure S_CT among the protrusion portions 56B may be located below the sacrificial contact structure S_CT, and might not include the grooves. Because the protrusion portions 56B2 do not include the grooves, each of the protrusion portions 56B2 may have a normal shape such as a circular shape or an elliptical shape.

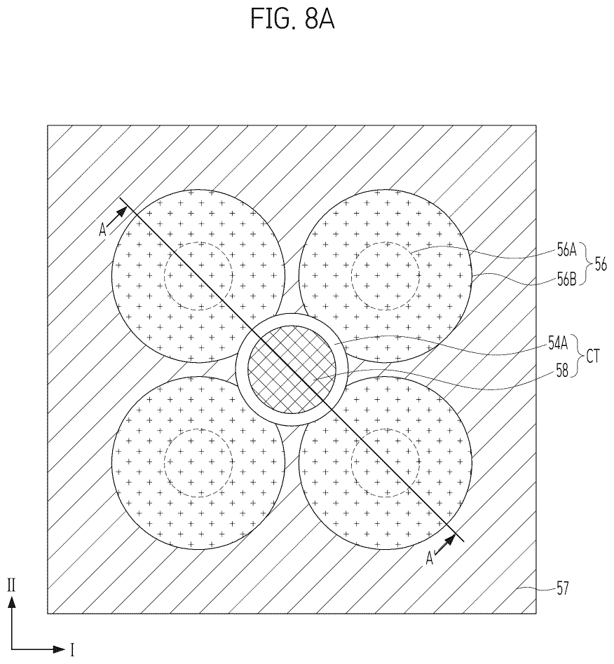

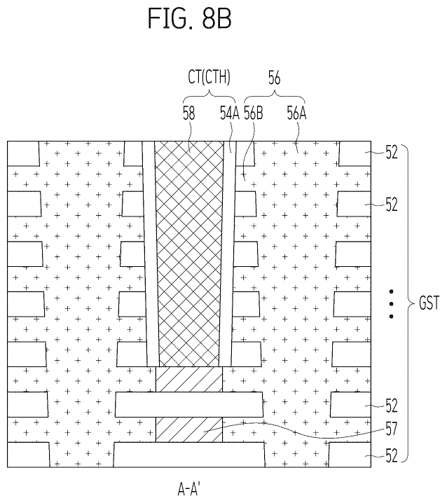

Referring to FIGS. 8A and 8B, the first material layers 51 may be replaced with conductive layers 57. As an example, the first material layers 51 may be removed through the slit penetrating through the stack ST, and the conductive layers 57 may be formed in regions where the first material layers 51 are removed. Through this process, a gate structure is formed including conductive layers 57 and the second material layers 52 that are alternately stacked.

Subsequently, the contact hole CTH may be reopened by removing the sacrificial layer 55. The insulating liner 54 may be exposed through the reopened contact hole CTH. Subsequently, an insulating spacer 54A may be formed on an inner wall of the contact hole CTH by etching the insulating liner 54. Subsequently, a contact plug 58 may be formed in the contact hole CTH.

According to the manufacturing method described above, it is possible to form the support structures 56 including the protrusion portions 56B by etching the first material layers 51 to form the second openings OP2. Accordingly, when the first material layers 51 are replaced with the conductive layers 57, the support structures 56 may stably support the stack ST. Even at a level at which the sacrificial contact structure S_CT does not exist, the stack ST may be stably supported through the protrusion portions 56B.

In addition, because the second openings OP2 are formed by etching the first material layers 51 so that the lower region of the sacrificial contact structure S_CT having a relatively small width is exposed, the second openings OP2 having a sufficient width may be formed, and the protrusion portions 56B having a sufficient width may be formed.

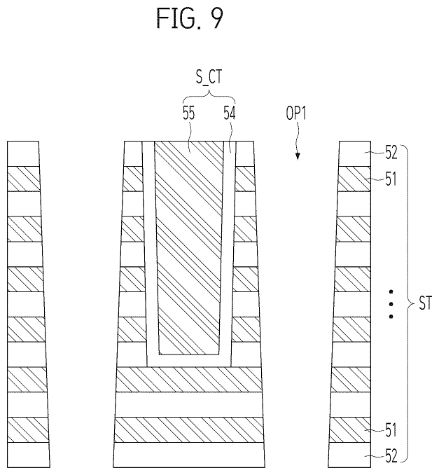

FIG. 9 is a diagram for describing a modified example of a manufacturing method of a semiconductor device in accordance with an embodiment of the present disclosure. Hereinafter, any content overlapping with the previously described content may be omitted.

FIG. 9 is a diagram corresponding to FIG. 7B described above. In FIG. 7B, the second material layers 52 exposed through the first opening OP1 are selectively etched, but this may be modified. As an example, the first material layers 51 and the second material layers 52 may be etched simultaneously. In such a case, irregularities might not be formed in the first opening OP1, and sidewalls of the first material layers 51 and the second material layers 52 may be aligned with each other.

Other processes may be the same as or similar to those described above.

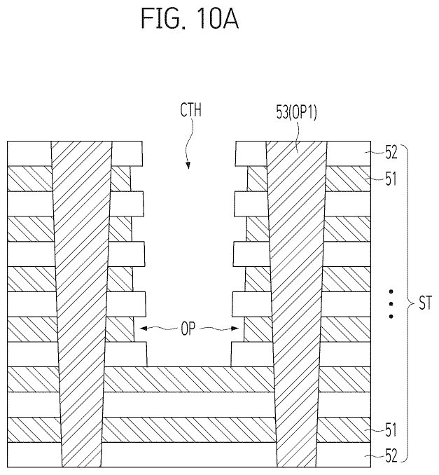

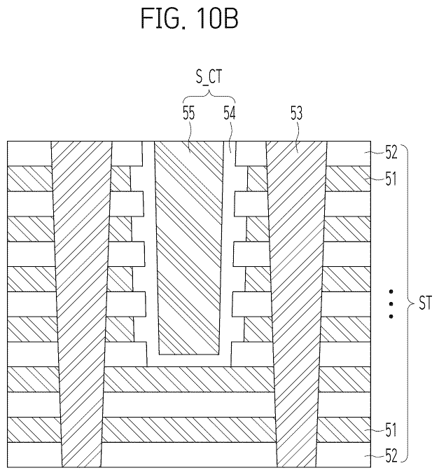

FIGS. 10A and 10B are simplified schematic diagrams for describing a modified example of a manufacturing method of a semiconductor device in accordance with an embodiment of the present disclosure. Hereinafter, any content overlapping with the previously described content may be omitted.

FIGS. 10A and 10B are simplified schematic diagrams corresponding to FIGS. 5B and 6B described above. In FIG. 5B, the sacrificial contact structure S_CT is formed after the contact hole CTH is formed, but this may be modified. As an example, a shape of the contact hole CTH may be changed.

Referring to FIG. 10A, openings OP may be formed by etching the first material layers 51 through the contact hole CTH. Through this, irregularities may be formed on an inner wall of the contact hole CTH, and the second material layers 52 may protrude into the contact hole CTH.

Referring to FIG. 10B, an insulating liner 54 and a sacrificial layer 55 may be formed in the contact hole CTH. The insulating liner 54 may extend along an inner surface of the contact hole CTH while filling the openings OP. Accordingly, an insulating spacer 54A formed in a subsequent process may include a sidewall pattern and protrusion patterns.

Other processes may be the same as or similar to those described above.

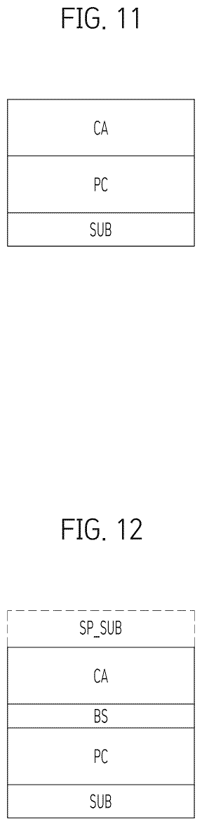

The structure and the manufacturing method according to the above-described embodiments may be applied to semiconductor devices having various structures. FIGS. 11 and 12 illustrate schematic configurations of semiconductor devices to which the above-described embodiments are applicable.

FIG. 11 is a configuration diagram of a semiconductor device in accordance with an embodiment of the present disclosure.

Referring to FIG. 11, the semiconductor device may include a substrate SUB, a peripheral circuit PC, and a memory cell array CA. Here, the peripheral circuit PC and the memory cell array CA may be formed on the same substrate.

The substrate SUB may include a semiconductor material. As an example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. As an example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. As an example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operating voltage and may include a contact plug, a wiring line, and the like.

The memory cell array CA may include memory cells. As an example, the memory cell array CA may include memory strings connected between a source line and a bit line, and each memory string may include stacked memory cells. As an example, the memory cell array CA may include memory cells connected between a word line and the bit line. The memory cell array CA may further include an interconnection structure.

FIG. 12 is a configuration diagram of a semiconductor device in accordance with an embodiment of the present disclosure.

Referring to FIG. 12, the semiconductor device may include a substrate SUB, a peripheral circuit PC, a bonding structure BS, and a memory cell array CA. Here, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. As an example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. As an example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be directly connected to each other without a bonding pad. As an example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring line, and the like, formed on different wafers may be electrically connected to each other without a separate bonding pad.

Other configurations may be the same as or similar to those described above with reference to FIG. 11.

It is also possible for the semiconductor device to have a structure in which embodiments described above with reference to FIGS. 11 and 12 are combined with each other or have a partially modified structure. In embodiments described with reference to FIGS. 11 and 12, locations of the memory cell array CA and the peripheral circuit PC may be changed. At least one memory cell array CA and/or at least one peripheral circuit PC may be additionally bonded in an embodiment described with reference to FIG. 11. As an example, a portion of the peripheral circuit PC may be located in the memory cell array CA.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure. Furthermore, the embodiments may be combined to form additional embodiments.

What is claimed is:

1. A semiconductor device comprising:
a gate structure including conductive layers and insulating layers that are alternately stacked;
support structures respectively located at vertices of a polygon defined on an upper surface of the gate structure and each support structure including a pillar extending through the gate structure and protrusion portions protruding from the pillar toward the conductive layers; and
a contact structure extending through the gate structure inside the polygon and electrically connected to a first conductive layer of the conductive layers,
wherein the protrusion portions include first protrusion portions in contact with the contact structure and second protrusion portions located below the contact structure.

2. The semiconductor device of claim 1, wherein the contact structure is located to correspond to a center of the polygon.

3. The semiconductor device of claim 1, wherein each of the first protrusion portions includes a groove surrounding a sidewall of the contact structure and has an asymmetric shape.

4. The semiconductor device of claim 3, wherein each of the second protrusion portions has a normal shape that does not include the groove.

5. The semiconductor device of claim 3, wherein the contact structure fills the grooves of the first protrusion portions.

6. The semiconductor device of claim 3, wherein the grooves of the plurality of first protrusion portions have different depths.

7. The semiconductor device of claim 1, wherein the support structures arranged along a perimeter of the polygon are spaced apart from each other.

8. The semiconductor device of claim 1, wherein the contact structure includes a lower region, an upper region, and a bowing region located between the lower region and the upper region, and the bowing region has a greater width than the lower region and the upper region.

9. The semiconductor device of claim 8, wherein each of the first protrusion portions includes a groove surrounding a sidewall of the contact structure, and the groove of the first protrusion portion corresponding to the bowing region has a greater depth than the groove of the first protrusion portion corresponding to the lower region.

10. The semiconductor device of claim 1, wherein each of the second protrusion portions has a circular shape or an elliptical shape in a plan view.

11. The semiconductor device of claim 1, wherein the contact structure comprises:
a contact plug electrically connected to the first conductive layer; and
an insulating spacer surrounding a sidewall of the contact plug.

12. The semiconductor device of claim 11, wherein the insulating spacer includes protrusion patterns protruding toward the conductive layers.

13. The semiconductor device of claim 12, wherein the protrusion patterns and the first protrusion portions are in contact with each other.

14. The semiconductor device of claim 1, further comprising:
a peripheral circuit; and
a bonding structure located between the peripheral circuit and the gate structure and electrically connecting the peripheral circuit and the contact structure to each other.

15. A semiconductor device comprising:
a gate structure including conductive layers and insulating layers that are alternately stacked;
support structures respectively located at vertices of a polygon defined on an upper surface of the gate structure and each including a pillar extending through the gate structure and protrusion portions protruding from the pillar toward the conductive layers; and
a contact structure extending through the gate structure inside the polygon and electrically connected to a first conductive layer of the conductive layers,
wherein the support structures arranged along a perimeter of the polygon are spaced apart from each other, and the contact structure is in contact with the protrusion portions of the support structures.

16. A manufacturing method of a semiconductor device, the manufacturing method comprising:
forming a stack including first material layers and second material layers that are alternately stacked;
forming sacrificial support structures extending through the stack and respectively located at vertices of a polygon defined on an upper surface of the stack;
forming a sacrificial contact structure extending through the stack inside the polygon and including a lower region, an upper region and a bowing region located between the lower region and the upper region, the bowing region having a greater width than the lower region and the upper region;
forming first openings by removing the sacrificial support structures;
forming second openings by selectively etching the first material layers through the first openings so that the lower region of the sacrificial contact structure is exposed;
forming support structures in the first openings and the second openings;
replacing the first material layers with conductive layers; and
replacing the sacrificial contact structure with a contact structure.

17. The manufacturing method of claim 16, further comprising, before the forming of the second openings, etching the second material layers through the first openings.

18. The manufacturing method of claim 16, further comprising, before the forming of the second openings, etching the first material layers and the second material layers through the first openings.

19. The manufacturing method of claim 16, wherein the forming of the sacrificial contact structure comprises:
forming a contact hole in the stack;
forming an insulating liner in the contact hole; and
forming a sacrificial layer in the insulating liner.

20. The manufacturing method of claim 19, wherein replacing the sacrificial contact structure with the contact structure comprises:
removing the sacrificial layer;
forming an insulating spacer by etching the insulating liner; and
forming a contact plug in the contact hole.

21. The manufacturing method of claim 16, wherein the support structures are in contact with the sacrificial contact structure.

22. The manufacturing method of claim 16, wherein the support structures are located at the vertices of the polygon, respectively, and the support structures arranged along a perimeter of the polygon are spaced apart from each other.

23. The manufacturing method of claim 16, wherein each of the support structures includes a pillar located in the first opening and protrusion portions located in the second openings.

24. The manufacturing method of claim 23, wherein the protrusion portions comprise:
first protrusion portions in contact with the sacrificial contact structure and having an asymmetric shape that includes grooves surrounding a sidewall of the sacrificial contact structure; and
second protrusion portions located below the sacrificial contact structure and having a normal shape that does not include the grooves.
